(19) United States
(12) Patent Application Publication
(10) Pub. No.: US 2011/0068088 A1
(43) Pub. Date: Mar. 24, 2011

(54) USE OF AN ELECTRICAL CONTACT MATERIAL FOR BLOWING AN ELECTRIC ARC

(75) Inventors: Laurent Doublet, Courville sur Eure (FR); Christine Bourda, Mainvilliers (FR); Didier Jeannot, Orrouer (FR); Pierre Ramoni, Montezillon (CH); Dominique Givord, Grenoble (FR); Sophie Rivoirard, Lans en Vercors (FR)

(73) Assignee: Metalor Technologies International SA, Neuchatel (CH)

(21) Appl. No.: 12/992,308

(22) PCT Filed: May 14, 2009
(86) PCT No.: PCT/EP2009/055879

§ 371 Date: Nov. 12, 2010

(30) Foreign Application Priority Data
May 22, 2008 (EP) 08156731.5

(51) Int. Cl. H01H 9/44; H05K 3/00; H01H 1/021

(52) U.S. Cl. 218/23; 29/829; 200/265

(57) ABSTRACT

Method of using a material including a conductive metal matrix and magnetic entities representing between 8 and 80% by weight of the material and including hard magnetic phases, the magnetic entities being non-magnetized but capable of being magnetized in an average orientation defined by the direction of a magnetic field applied to the material, in order to blow an electric arc between two electrical contact pads, at least one of which includes the material.

### TECHNICAL FIELD

The present invention relates to the field of electric contacts. More particularly, it relates to the use of an electrical contact material with an effect of extinguishing an arc.

### STATE OF THE ART

Such a type of material finds its application mainly for making so-called “low voltage” contacts, i.e. for which the operating range is approximately located between 10 and 1,000V and between 1 and 10,000 A. These contacts are generally used in the home, industrial and automotive fields, both with DC current and AC current, for switches, relays, contactors and circuit breakers, etc.

When a pair of electric contact pads are open under a voltage, the current continues to flow from one pad to the other by ionizing the gas which it crosses. This ionized gas column, commonly called an “electric arc”, has a maximum length which depends on different parameters such as the nature and the pressure of the gas, the voltage on the terminals, the contact material, the geometry of the apparatus, the impedance of the circuit, etc.

The energy released by the electric arc is sufficient for melting the material forming the pads, which not only causes degradation of the metal portions but also sometimes their weld with the consequence of blocking the apparatus.

In the alternating current applications, the passing of the voltage through zero facilitates the cutting-off of the arc. Nevertheless, certain protection apparatuses have to cut off very high currents, which cause sufficiently powerful arcs for damaging the contacts.

On the other hand for direct current applications, the electric arcs are very stable, especially when the voltage is clearly greater than 10V. A solution for cutting off the arc consists of increasing its length so that it becomes unstable and disappears by itself. For a voltage of 14V, a distance of the order of one millimeter is sufficient while for a voltage of 42V, particularly when an inductive load is present, this distance may be of several centimeters. This seriously complicates the design of cut-off apparatuses and the duration of the generated arcs strongly reduces their life-time.

The problem is most particularly posed in the automotive industry which contemplates the use of circuits with 42V DC or even more in order to adapt to the increasingly large number of electric devices present in cars (up to a hundred motors in a top-of-the-range vehicle). At such voltages, the benefit of limiting problems related to arcs becomes primordial.

Thus, the materials of the electric contacts should meet the three following requirements:
a low and stable contact resistance in order to avoid excessive heating when the current flows through it;
good resistance to welding in the presence of an electric arc; and
low erosion under the effect of the arc.

In order to meet these partly contradictory requirements, a solution consists of using pseudo-alloys including a silver or copper matrix and, inserted in this matrix, a fraction consisting of about 10 to 50% by volume of refractory particles (for example, Ni, C, W, WC, CdO, SnO₂ particles) with a size generally comprised between 1 and 5 μm. The thereby obtained material better withstands the energy released by the electric arc. Although this is an interesting solution, with this method it is not possible to limit melts and because of their repetition, problems of erosion and of welding of the pads may occur in the short or medium term.

Another solution, described in U.S. Pat. No. 3,626,124 consists of using a material comprising mono-domain magnetic particles. Such particles are spontaneously magnetized along a random orientation in the absence of an applied external field. These particles are therefore initially magnetized and do not need any external magnetization source. The field generated by each magnetized particle acts on the cut-off arc, facilitating its blowing out. The described particles remain monodomain particles even as a result of heating beyond their Curie temperature so that the blowing efficiency is not affected by the heating due to the cut-off arc, upon previous openings of the contacts. However, each particle acts individually on the cut-off arc so that the magnetic blowing effect is very small. This solution is therefore not satisfactory.

Moreover, when in alternating current, the question is to produce protective apparatuses (circuit breakers) capable of cutting off very high currents, resorting to auxiliary means has been suggested for facilitating extinction of the arc or avoiding its re-igniting: electromagnetic or pneumatic blowing out.

For example, such an electromagnetic extinction solution by devices external to the actual contact is described in document EP 1 482 525. The latter discloses a magnetic device placed at a distance from the contact and which generates a magnetic field extending an electric arc which would occur between the pads, with the purpose of extinguishing it. However, the overcost, the congestion and the overweight caused by this solution make it problematic, particularly for applications to automobiles.

Replacing the gas present in the space separating the two contacts with a very stable gas and therefore difficult to ionize like SF₆, has i.a. been suggested. However, this solution is complex to apply.

An object of the present invention is therefore to overcome these drawbacks, by proposing the use of an electrical contact material for making contact pads, the operation of which is neither altered in the short term nor in the long term by the energy of an electric arc.

### DISCLOSURE OF THE INVENTION

More specifically, the invention relates to the use of a material including a matrix in conductive metal and magnetic entities representing between 8 and 80% by weight of the material and comprising hard magnetic phases, said magnetic entities not being magnetized and being magnetizable with an average orientation, defined by the direction of a magnetic field applied on said material, in order to blow out an electric arc between two pads of electrical contacts, at least one of which comprises said material, and to thereby reduce the duration of the arc.

The invention also relates to the use of a material including a matrix in conductive metal and magnetic entities representing between 8 and 80% by weight of the material and comprising hard magnetic phases, said magnetic entities initially non-magnetized having been magnetized with an average orientation, defined by the direction of a magnetic field applied on said material, in order to blow out an electric arc between two pads of electric contacts, at least one of which comprises said material, and to thereby reduce the duration of the arc.

Alternatively, the material may further include a refractory fraction stable at a temperature above 900° C.

Advantageously, at least one of the phases of the magnetic entities is a magnetic compound based on rare earths.

In order to allow a use according to the invention, said material is capable of generating a magnetic induction field, measured at its surface, of greater than 20 mT, preferably greater than 60 mT, and more preferably greater than 100 mT.

Particularly remarkable effects on the extinction of an electric arc were observed for a use according to the invention, according to which said pads define between them an axis, at least one of said pads being made in said material and having magnetization generating a magnetic field perpendicular to said axis.

Advantageously, at least one of said pads which comprises said material with the magnetic entities, has a overlayer comprising a material selected from silver and copper.

According to another aspect, the present invention relates to a constitutive material of an electric contact pad including a matrix in conductive metal and magnetic entities representing between 8 and 80% by weight of the material and comprising hard magnetic phases, said magnetic entities not being magnetized and being magnetizable with an average orientation, defined by the direction of a magnetic field applied on said material, at least one of the magnetic phases being a compound based on rare earths, except for samarium.

The present invention also relates to a constitutive material of an electrical contact pad including a matrix in conductive metal and magnetic entities representing between 8 and 80% by weight of the material and comprising hard magnetic phases, said magnetic entities initially non-magnetized having been magnetized with an average orientation, defined by the direction of a magnetic field applied on said material, at least one of the magnetic phases being a compound based on rare earths, except for samarium.

According to another aspect, the present invention relates to a method for making an electric contact pad comprising the following steps:
elaborating a material from silver or copper in order to form the matrix of said material and from magnetic entities comprising hard magnetic phases, said magnetic entities being non-magnetized, at least one of the magnetic phases being a compound based on rare earths,
shaping the pad,
assembling it on a support, and
magnetizing the pad.

According to another aspect, the invention relates to a pair of pads of electrical contacts, said pads defining between them an axis, in which at least one of said pads is made in a material as defined above and has magnetization generating a magnetic field perpendicular to said axis.

In the case of direct current, very good results have also been observed for a pair of pads of electrical contacts comprising at the cathode, a contact pad made in a material as defined above.

### SHORT DESCRIPTION OF THE DRAWINGS

The invention will be better understood upon reading the description which follows, made with reference to the appended FIGURE, illustrating different orientations of the magnetic field exhibited by the pads of an electrical contact.

### EMBODIMENT(S) OF THE INVENTION

The contact material used in the present invention essentially consists of:
a matrix of a conductive metal, generally silver or copper; and
magnetic entities representing between 8 and 80% by weight of the material and comprising hard magnetic phases, said magnetic entities initially being non-magnetized and being magnetizable with an average orientation, defined by the direction of the magnetic field applied on said material.

Consequently, the material used according to the invention initially contains multidomain magnetic entities forming an initially globally non-magnetized assembly, and which should then be magnetized by applying a field. Preferably, the material used according to the invention does not initially contain any spontaneously magnetized monodomain entities.

Preferably, the magnetic entities represent between 10 and 50% by weight of a material, preferably between 12 and 30% by weight, and more preferably between 18 and 22% by weight of said material.

The magnetic entities comprise magnetic phases which may be obtained from one or more hard ferromagnetic or ferromagnetic compounds. Advantageously, they are selected from compounds based on rare earths, among which mention may be made of so-called compounds of the RE-Fe—B type, (RE an acronym for rare earth). Preferably the RE is neodymium or praseodymium. Other compounds of the RE-M type may be used, the RE being preferably La, Gd, Y or Lu, of the ⅕, 1/7 or 2/17 type, and M being in majority Co or Fe and which may contain Cu, Zr, Al and other minority elements. Compounds of the RE-Fe—N type may also be used.

Other compounds such as those of the Pt(Fe,Co) family may also be suitable, or compounds of the barium or strontium ferrite type.

Other materials may further be contemplated, the essential point being that the magnetic entities have a sufficient coercitive field and remanent induction for allowing their use in the targeted applications, both of these parameters may be evaluated by simple experimental tests. Indeed, as this will be explained hereafter, it requires that the contact generate a certain magnetic field so as to destabilize a possible electric arc occurring between the pads. It is notably necessary that after having itself being exposed to a magnetic field, the material has sufficient remanent induction stable over time, for long term use. This induction, obtained by magnetization of the pads under an external magnetic field, may be characterized by the magnetic field generated at the surface of the pads, and persisting after suppression of the applied magnetic field. As an indication, the field generated at the surface should be greater than 20 mT, preferably greater than 60 mT, and more preferably greater than 100 mT, as measured with a Hall effect probe distributed by Lakeshore.

Optionally, the matrix includes a refractory fraction, stable at a temperature above 900° C. The refractory fraction may include one of more of the elements selected in the following group: CdO, SnO₂, ZnO, Bi₂O₃, C, WC, MgO, In₂O₃, as well as Ni, Fe, Mo, Zr, W or their oxides.

The refractory fraction is added in an amount so that the percentage of the magnetic entities is at least 8% and that the amount of conductive metal is at least 20%.

Advantageously, the magnetic entities are dispersed in the matrix, either regularly, or according to a concentration gradient, or further in localized blocks.

Additionally, the material may also contain dopants or minor additives, facilitating application of the material, which may for example be Ni, Co, Fe, Bi, Re, Zr and their oxides.

The material described above is used for making pads of electrical contacts. The first steps of the method for elaborating the material and for shaping the contact pads are current and known to one skilled in the art who may choose between several techniques. Further, the method includes an additional step for magnetizing the material on the already elaborated pads.

In particular, and without it being necessary to further detail this for one skilled in the art who may, with a few currently used tests, apply the techniques hereafter, the elaboration of the material used according to the invention may be achieved by:
powder metallurgy,
a chemical route for precipitating salts from a solution,
atomization,
deposition of a thin or thick layer, or
extrusion from a billet or a mixture of powders.

Advantageously, the step for elaborating the material may be achieved by powder metallurgy, one of the magnetic entities being nanostructured RE-Fe—B wherein RE is a rare earth element.

A preferential direction of the magnetic entities may be obtained by applying a suitable method upon elaborating the pads (pressure, magnetic field, heat treatment). This operation is not indispensable but it allows an increase in the magnetization of the pads induced by the applied field after elaborating the pads.

It should be noted that in a non-limiting way, the use as a starting material for forming the magnetic entities of the contact, of a nanostructured ribbon of RE-Fe—B obtained by a rapid solidification technique, particularly by the technique known as melt spinning, gives excellent results. It is not necessary to further describe this technique known to one skilled in the art. To summarize, it will be retained that it consists of casting through a nozzle, molten metal contained in a reservoir, and of bringing a trickle of liquid metal into contact with a cylinder, for example in copper, rotating at high speed. By this technique, RE-Fe—B cools down by assuming a microstructure, which allows it to exhibit remarkable hard magnetic characteristics with view to the targeted use.

RE-Fe—B may be associated with other magnetic materials for optimizing the magnetic properties of the assembly, RE-Fe—B advantageously representing at least 50% by weight of the magnetic entities.

Contact pads are then shaped by cutting out strips, stamping wires, unit compression. They are then positioned on a suitable support, by any traditional assembly method for electric contacts, in particular: resistance welding, resistance brazing, induction brazing, flame or oven brazing, crimping, inlay . . . with view to their use as electrical contacts.

Alternatively, the material used according to the invention may be shaped as a washer or a layer, forming a magnetic system, made integral with a traditional electrical contact pad by inlay, welding, brazing or riveting, or even by depositing layer(s). In the latter case, the magnetic material, the contact material or both, may appear as one or several layers. The magnetic system may also be used as a mechanical support and for feeding current to the electrical contact. Advantageously it is possible to adapt the magnetic system according to the alternative in existing installations, by retaining the initial contact material, since it only occupies a small additional space of the contact unlike electromagnetic members of the prior art.

In the shaped pads, the magnetic entities are not magnetized. The pads then have to be subject to the magnetization step by applying a magnetizing magnetic field in order to impart to the non-magnetized magnetic entities, global magnetization according to an average orientation defined by the applied field. The pads may then fully play their role of arc blower or extinguisher. This operation may take place in the factory, after elaborating the pad. It may also take place at the user's, before or after final mounting of the contact. It is performed by exposing the pads to a magnetic field with an intensity comprised between 0.5 and 30 T, preferably between 1 and 30 T, and still more preferably between 1 and 10 T. Thus, according to the invention, the material used as pads comprises initially non-magnetized magnetic entities which are either magnetizable by applying a magnetic field at the user's, or already magnetized by application of a magnetic field at the factory.

By this application of a magnetic field with suitable direction and intensity, on the already elaborated pads, global magnetization of the pads is generated, the orientation of which is defined by the applied field. The result of this is that a magnetic field is generated in the environment of the pad. This field acts on the cut-off arc and contributes to blowing it out.

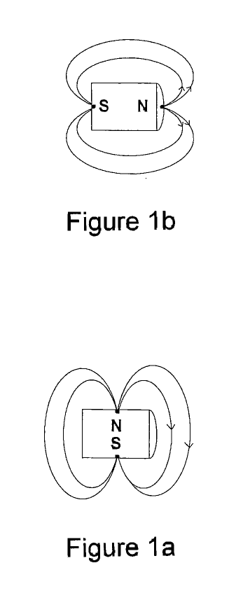

The field may notably be applied parallel or preferably perpendicularly to the longitudinal axis of a pad, so that the latter has field lines as illustrated in FIGS. 1a and 1b respectively. The conditions of the magnetization step (duration and intensity of the field) are adapted to the magnetic material so that, after having undergone the magnetization step, the pads are source of a magnetic induction field which, measured at their surface, is greater than 20 mT, preferably than 60 mT, and more preferably greater than 100 mT.

The thereby obtained pads are then applied in electrical contacts formed with two pads defining between them a first axis. The contact may only include a single pad obtained according to the method above, positioned in the case of a direct current circuit, at the anode or at the cathode. It is also possible that both pads forming the contact be made in a magnetic material used according to the invention. Various orientations of magnetic fields are possible and conceivable, for example, when a single magnetized pad is used, the field which it generates may be oriented parallel or perpendicularly to the first axis.

Alternatively, the pad may comprise an overlayer deposited on the magnetic material. Such an overlayer comprises a conductive material selected from silver and copper and optionally a refractory compound selected from the group comprising CdO, SnO₂, ZnO, Bi₂O₃, C, WC, MgO, In₂O₃ compounds as well as Ni, Fe, Mo, Zr, W or their oxides.

With this over-layer it is advantageously possible to insulate the magnetic entities from the pad of the contact surface and thereby reduce the risks of welding upon closing. Indeed, the blowing effect may be attenuated by ionization of the constitutive elements of the magnetic compound, the latter being able to increase the contact resistance and to promote welding. Anyhow, the extreme surface of the contact is strongly heated under the effect of the arc so that the magnetic properties of the surface entities are generally destroyed during operation. The overlayer should be sufficiently thin so that the field generated by the underlying magnetic entities in the area of the arc remains sufficiently intense, and possibly sufficiently thick so as not to be completely melted under the effect of the arc. However, it is found that reduction of the duration of the arc as obtained according to the invention leads to very low erosion. Thus, the overlayer may have a thickness comprised between 0.05 mm and 3 mm, preferably comprised between 0.1 mm and 2 mm, and more preferably comprised between 0.2 mm and 1 mm.

The following examples illustrate the present invention without however limiting the scope thereof.

### Example 1

The elaboration of the material is accomplished by powder metallurgy. Thus, a ribbon of Nd—Fe—B produced by the technique known as “melt spinning” is reduced into powder under argon, by ball milling, until a grain size comprised between 1 and 50 μm is obtained. The duration of this operation is about 5 hrs.

The thereby obtained powder is mixed with powdered silver, the particles of which have an average diameter comprised between 15 and 50 μm. The mixture is accomplished in a mass proportion of 80% of silver and 20% of magnetic entity EM powder. A magnetic material constitutive of an electrical contact pad is obtained.

An electrical contact pad is then shaped by unit compression and compacted under a pressure of 700 MPa.

Next, the pad is sintered in vacuo at 400° C. for about 30 minutes.

The pad is then assembled on a support according to one of the aforementioned techniques, so as to be used in an electrical contact.

Finally, the pad is magnetized by exposing it to a magnetic field of 8 T. The pad is oriented perpendicularly to the magnetic field, as illustrated in FIG. 1a, so that it exhibits magnetization perpendicular to its longitudinal axis. With the magnetization conditions above, the pad is source of a remanent induction field of about 60 mT at the surface.

The pad obtained above is then used in a contact of an electrical circuit of the resistive type, operating under a DC voltage of 42 V, with an intensity of 37.5 A. As an example, only a magnetized pad is positioned at the cathode, the other one being in silver.

With this configuration (perpendicular magnetization, a single magnetized pad at the cathode), the opening arc duration is measured. Closure tests are also carried out for simulating the risks of welding, under the same conditions and for the opening, but with a current of 90 A. The percentage of welding obtained is measured, the rupture force is greater than 0.1 N.

The obtained results are copied into Table 1 below.

### Example 2

Example 1 is reproduced by replacing 6% by weight of silver of the matrix with 6% by weight of a refractory compound (SnO₂).

The same tests as for Example 1 are conducted. The obtained results are copied into Table 1 below.

### Example 3

An overlayer with a thickness of 0.6 mm is applied on the magnetic material of the pad obtained in Example 1. Said overlayer comprises 100% silver.

The same tests as for Example 1 are conducted. The obtained results are copied into Table 1 below.

### Examples 4-6

As a comparison, Example 1 is reproduced while not submitting the pad to magnetization (Example 4) or by using other materials for making the pads of the contact (Examples 5 and 6).

The same tests as for Example 1 are conducted. The composition of these materials as well as the results obtained with the elaborated pads, are copied into Table 1 below:

TABLE 1

| | | Opening arc | Welding % |
|---|---|---|---|
| Example | Composition of the contacts | duration (ms) | upon closure |
| 1 (inv.) | Ag(80)EM(20) − Ag | 3 | 60 |
| 2 (inv.) | Ag(74)SnO₂(6)EM(20) − Ag | 3 | 9 |
| 3 (inv.) | Ag(80)EM(20) + overlayer − | 3 | 1 |
| | Ag | | |
| 4 (comp.) | Ag(80)EM(20) (non- | 9 | 60 |
| | magnetized) − Ag | | |
| 5 (comp.) | Ag—Ag | 9 | 7 |
| 6 (comp.) | AgSnO₂10/AgSnO₂10 | 24 | 3 |

The results obtained in Table 1 show that the use according to the invention of the magnetic material described above for making electrical contact pads allows reduction in the arc duration upon opening by 9 ms, or even 24 ms to 3 ms. Example 4 also shows the importance of the magnetization step of the pad since a contact comprising a non-magnetized pad has an arc duration upon opening of 9 ms while the contact comprising the magnetized pad has a arc duration upon opening of 3 ms.

Further, the addition of a refractory compound (Example 2) or the use of an overlayer (Example 3) allows a strong reduction in the welding tendency of the pads consisting of the magnetic material defined above without significantly affecting the arc duration upon opening. By using an overlayer it is possible to obtain particularly interesting results.

1-21. (canceled)

22. A method for blowing out an electric arc between two pads of electrical contacts, comprising a step of providing at least one of said pads comprising a material including a matrix in conductive metal and magnetic entities representing between 8 and 80% by weight of the material and comprising hard magnetic phases, said magnetic entities being non-magnetized initially, having been magnetized with an average orientation, defined by the direction of a magnetic field applied on said material.

23. The method according to claim 22, wherein the magnetic entities represent between 10 and 50% by weight of said material.

24. The method according to claim 23, wherein the magnetic entities represent between 12 and 30% by weight of said material.

25. The method according to claim 22, wherein said material further includes a refractory fraction stable at a temperature above 900° C.

26. The method according to claim 25, wherein said refractory fraction includes one or more of the elements selected from the group consisting of CdO, SnO₂, ZnO, Bi₂O₃, C, WC, MgO, In₂O₃, as well as Ni, Fe, Mo, Zr, W and their oxides.

27. The method according to claim 22, wherein at least one of the phases of the magnetic entities is a hard magnetic compound based on rare earths.

28. The method according to claim 27, wherein the magnetic entities are nanostructured RE-Fe—B alloys, where RE is a rare earth element.

29. The method according to claim 28, wherein RE is neodymium or praseodymium.

30. The method according to claim 22, wherein the material is capable of generating a magnetic induction field as measured at its surface, of greater than 20 mT.

31. The method according to claim 30, wherein the material is capable of generating a magnetic induction field as measured at its surface, of greater than 60 mT.

32. The method according to claim 22, wherein said pads define between them an axis, at least one of said pads being made in said material and having magnetization generating a magnetic field perpendicular to said axis.

33. The method according to claim 22, wherein at least one of said pads comprising the magnetic entities has an overlayer comprising a material selected from silver and copper.

34. The method according to claim 33, wherein said overlayer further comprises a refractory compound selected from the group consisting of CdO, SnO₂, ZnO, Bi₂O₃, C, WC, MgO, In₂O₃, as well as Ni, Fe, Mo, Zr, W and their oxides.

35. The method according to claim 33, wherein said overlayer has a thickness comprised between 0.05 mm and 3 mm.

36. The method according to claim 34, wherein said overlayer has a thickness comprised between 0.1 mm and 2 mm.

37. A material of an electrical contact pad including a matrix in conductive metal and magnetic entities representing between 8 and 80% by weight of the material and comprising hard magnetic phases, said magnetic entities being non-magnetized initially, having been magnetized with an average orientation, defined by the direction of a magnetic field applied on said material, at least one of the magnetic phases being a compound based on rare earths, except for samarium.

38. A method for manufacturing an electric contact pad comprising the following steps:
elaborating a material from silver or copper in order to form the matrix of said material and from magnetic entities comprising hard magnetic phases, said magnetic entities being non-magnetized, at least one of the magnetic phases being a compound based on rare earths,
shaping the pad,
assembling it on a support, and
magnetizing the pad.

39. The method according to claim 38, wherein the step for elaborating the material is performed by powder metallurgy, one of the magnetic entities being nanostructured RE-Fe—B, wherein RE is a rare earth element.

40. The method according to claim 38, wherein the magnetization step is performed in such a way that said pad generates a magnetic induction field as measured at its surface, of greater than 20 mT.

41. A pair of pads of electrical contacts, said pads defining between them an axis, wherein at least one of said pads is made in a material including a matrix in conductive metal and magnetic entities representing between 8 and 80% by weight of the material and comprising hard magnetic phases, said magnetic entities being non-magnetized initially, having been magnetized with an average orientation, defined by the direction of a magnetic field applied on said material, at least one of the magnetic phases being a compound based on rare earths, except for samarium and has magnetization generating a magnetic field perpendicular to said axis.

42. A pair of pads of electrical contacts, comprising at the cathode, a contact pad made in a material including a matrix in conductive metal and magnetic entities representing between 8 and 80% by weight of the material and comprising hard magnetic phases, said magnetic entities being non-magnetized initially, having been magnetized with an average orientation, defined by the direction of a magnetic field applied on said material, at least one of the magnetic phases being a compound based on rare earths, except for samarium.

43. An electrical contact pad made in a material including a matrix in conductive metal and magnetic entities representing between 8 and 80% by weight of the material and comprising hard magnetic phases, said magnetic entities being non-magnetized initially, having been magnetized with an average orientation, defined by the direction of a magnetic field applied on said material, at least one of the magnetic phases being a compound based on rare earths, except for samarium, said pad having an overlayer comprising a material selected from silver and copper and optionally a refractory compound selected from the group consisting of CdO, SnO₂, ZnO, Bi₂O₃, C, WC, MgO, In₂O₃, as well as Ni, Fe, Mo, Zr, W and their oxides.
